(19) United States
(12) Patent Application Publication
(10) Pub. No.: US 2025/0263827 A1
(43) Pub. Date: Aug. 21, 2025

(54) MASK ASSEMBLY TRANSFER DEVICE AND MASK ASSEMBLY TRANSFER METHOD USING THE SAME

(71) Applicant: Samsung Display Co., Ltd., Yongin-si (KR)

(72) Inventors: BYUNG IK KONG, Yongin-si (KR); YONGHWAN KIM, Yongin-si (KR); JUNGHYUN AHN, Yongin-si (KR); JAESUK MOON, Yongin-si (KR); SEUNGJIN LEE, Yongin-si (KR)

(73) Assignee: Samsung Display Co., Ltd., Yongin-si (KR)

(21) Appl. No.: 18/972,083

(22) Filed: Dec. 6, 2024

(30) Foreign Application Priority Data
Feb. 15, 2024 (KR) 10-2024-0022036

(51) Int. Cl. C23C 14/04

(52) U.S. Cl. CPC C23C 14/042

(57) ABSTRACT

Provided is a mask assembly transfer device including a stage for supporting a mask assembly, a magnetic member disposed on the stage, and a plate disposed between the stage and the magnetic member. The mask assembly includes masks arranged in a first direction and support sticks arranged in the first direction, each extending in a second direction. The magnetic member includes a support part and first magnetic bodies and second magnetic bodies which are coupled to the support part and arranged in the second direction, each extending in the first direction. The first magnetic bodies and the second magnetic bodies have polarities different from each other and are alternately arranged in the second direction.

### CROSS-REFERENCE TO RELATED APPLICATION

This application claims priority to and benefits of Korean Patent Application No. 10-2024-0022036 under 35 U.S.C. § 119, filed on Feb. 15, 2024, in the Korean Intellectual Property Office (KIPO), the entire contents of which are incorporated herein by reference.

### BACKGROUND

### 1. Technical Field

The disclosure herein relates to a mask assembly transfer device for transferring a mask assembly including large-area masks and a mask assembly transfer method using the same.

### 2. Description of the Related Art

In general, a light-emitting element is disposed in each pixel in a light-emitting display device. The light-emitting element may include a light-emitting pattern disposed between electrodes which are spaced apart from each other. The light-emitting pattern included in each pixel may be divided into multiple groups.

A mask assembly may be used to deposit pixels on a disposition substrate. Functional layers may be formed by disposing a deposition substrate on the mask assembly and depositing a deposition material onto the deposition substrate. As a large-sized panel is developed, a size of a mask increases, and a device for safely transferring a mask assembly including large-area masks is required.

### SUMMARY

Embodiments provide a mask assembly transfer device for transferring, without deformation, a mask assembly including large-area masks, and a mask assembly transfer method using the same.

However, embodiments of the disclosure are not limited to those set forth herein. The above and other embodiments will become more apparent to one of ordinary skill in the art to which the disclosure pertains by referencing the detailed description of the disclosure given below.

An embodiment may include a mask assembly transfer device including: a stage supporting a mask assembly; a magnetic member disposed on the stage; and a plate disposed between the stage and the magnetic member, wherein the mask assembly has masks arranged in a first direction and disposed on the stage, and support sticks disposed between the masks and arranged in the first direction, each extending in a second direction crossing the first direction, the magnetic member has a support part, and first magnetic bodies and second magnetic bodies which are coupled to the support part and arranged in the second direction, each extending in the first direction, and the first magnetic bodies and the second magnetic bodies have polarities different from each other and are alternately arranged in the second direction.

In an embodiment, the plate may include at least one of glass and acrylic.

In an embodiment, the plate may move downward to make contact with the mask assembly.

In an embodiment, the magnetic member may move downward to make contact with the plate.

In an embodiment, in case that a magnetic force is applied to the first magnetic bodies and the second magnetic bodies, the mask assembly may be attached to the plate.

In an embodiment, the mask assembly may be attached, by the magnetic force, to the magnetic member, with the plate disposed between the mask assembly and the magnetic member, and the magnetic member may transfer the mask assembly from the stage.

In an embodiment, the first magnetic bodies and the second magnetic bodies may each be separable from the support part and replaceable.

In an embodiment, each of the masks may include a deposition part in which deposition openings are formed, and a body part surrounding the deposition part, and among body parts of each of the masks, the body parts adjacent to each other in the first direction may be coupled to the support sticks.

In an embodiment, the body parts may be coupled to the support sticks through a welding process.

In an embodiment, the first magnetic bodies and the second magnetic bodies may each cross the support sticks in plan view.

In an embodiment, each of the masks may have a width in a range of about 400 mm to about 1000 mm in the first direction.

In an embodiment, among the masks, each of the masks disposed on an outermost side in the first direction may further include a clamping part connected to the body part.

In an embodiment, the mask assembly transfer device may further include additional support sticks overlapping the clamping part and the body part, wherein the clamping part and the body part may be coupled to the additional support stick through a welding process.

In an embodiment, the support sticks may be disposed between the masks and the stage.

In an embodiment, the masks and the support sticks may include an invar.

In an embodiment, a mask assembly transfer method including: disposing a mask assembly on a stage; moving a plate downward so that the plate makes contact with the mask assembly; moving a magnetic member downward so that the magnetic member makes contact with the plate; attaching the mask assembly to the magnetic member, with the plate disposed between the mask assembly and the magnetic member, by applying a magnetic force to the magnetic member; and transferring the magnetic member to outside of the stage while the mask assembly is attached to the magnetic member, wherein the mask assembly may include masks arranged in a first direction and disposed on the stage, and support sticks disposed between the masks and arranged in the first direction, each extending in a second direction crossing the first direction, the magnetic member has first and second magnetic bodies arranged in the second direction, each extending in the first direction, and the first magnetic bodies and the second magnetic bodies have polarities different from each other and are alternately arranged in the second direction.

In an embodiment, the plate may include at least one of glass and acrylic.

In an embodiment, the first magnetic bodies and the second magnetic bodies may each cross the support sticks in plan view.

In an embodiment, the support sticks may be disposed between the masks and the stage.

In an embodiment, each of the masks may have a width in a range of about 400 mm to about 1000 mm in the first direction.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and, together with the description, serve to explain principles of the disclosure. In the drawings:

FIG. 1 is a schematic cross-sectional view of a deposition apparatus according to an embodiment;

FIG. 2 is a schematic plan view of a mask assembly according to an embodiment;

FIG. 3 is a schematic plan view of an initial mask assembly according to an embodiment;

FIG. 4 is a schematic plan view of an initial mask assembly according to an embodiment;

FIGS. 5 to 9 are schematic cross-sectional views illustrating a mask assembly transfer method according to an embodiment;

FIG. 10 is a schematic plan view of a mask assembly and a magnetic body according to an embodiment;

FIG. 11 is a schematic plan view of a mask assembly and magnetic bodies according to Comparative Examples;

FIG. 12 is a schematic cross-sectional view taken along line I-I′ in FIG. 11;

FIG. 13 is a schematic cross-sectional view taken along line II-II′ in FIG. 11;

FIG. 14 is a schematic perspective view of a display panel according to an embodiment of; and

FIG. 15 is a schematic cross-sectional view of a display panel according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in an embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Throughout the specification, when an element is referred to as being “connected” to another element, the element may be “directly connected” to another element, or “electrically connected” to another element with one or more intervening elements interposed therebetween. Also, when an element is referred to as being “in contact” or “contacted” or the like to another element, the element may be in “electrical contact” or in “physical contact” with another element; or in “indirect contact” or in “direct contact” with another element.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

It will be understood that when an element such as a layer, film, region, or substrate is referred to as being “on” or “over” another element, it can be directly on the other element or intervening element(s) may also be present. In contrast, when an element is referred.

The term overlap may include layer, stack, face or facing, extending over, covering or partly covering or any other suitable term as would be appreciated and understood by those of ordinary skill in the art.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be described with reference to the accompanying drawings.

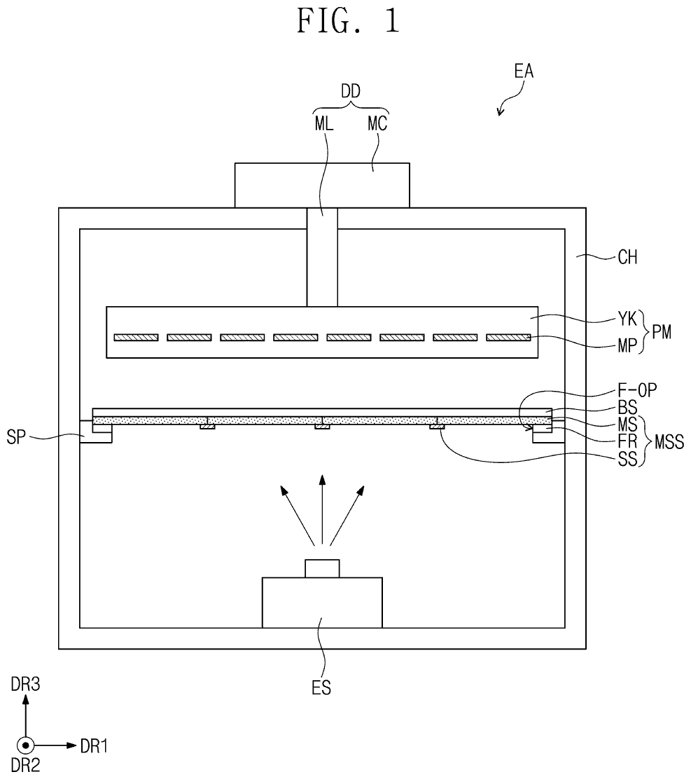

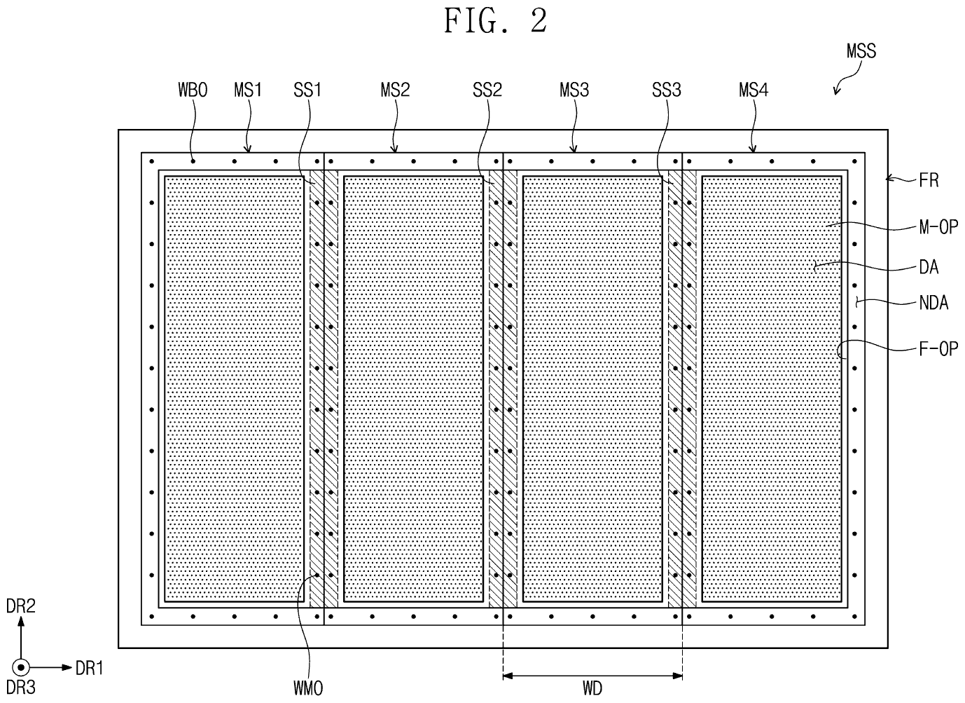

FIG. 1 is a schematic cross-sectional view of a deposition apparatus according to an embodiment. FIG. 2 is a plan view of a mask sheet according to an embodiment.

Referring to FIG. 1, a deposition apparatus EA according to the embodiment may include a chamber CH, a deposition source ES, a mask sheet MSS, a deposition substrate BS, a pressing part PM, and a transfer part DD. The deposition apparatus EA may be an apparatus for depositing an organic material or a conductive material onto the deposition substrate BS.

The chamber CH provides an internal space in which a deposition process may be performed. The deposition source ES, the mask sheet MSS, the deposition substrate BS, the pressing part PM, and a transfer rod ML of the transfer part DD may be disposed in the internal space. A holder part SP may be disposed inside the chamber CH. The mask sheet MSS may be placed on the holder part SP.

The deposition source ES may provide a deposition material to the deposition substrate BS. For example, the deposition source ES may vaporize a deposition material, which contains at least any one of an inorganic material or an organic material, and spray the vaporized deposition material in a direction toward the mask sheet MSS. The deposition material may pass through the mask sheet MSS to be deposited onto the deposition substrate BS. The deposition source ES may be implemented in a manner of heating and vaporizing the deposition material at a high temperature. According to an embodiment, the deposition apparatus EA may further include a transfer unit for moving the deposition source ES in a first direction DR1 and a second direction DR2.

The pressing part PM may include a magnetic plate MP and a support plate YK. According to an embodiment, the pressing part PM may further include a cooling plate disposed between the deposition substrate BS and the support plate YK.

The magnetic plate MP may be disposed inside the support plate YK. The magnetic plate MP may generate a magnetic force while the deposition substrate BS and the mask sheet MSS are in close contact with each other and may pull masks MS. The magnetic plate MP may prevent a lifting phenomenon caused by a difference in curvature between the deposition substrate BS and the masks MS and thus prevent the occurrence of a shadowing effect which is a deposition defect. The magnetic plate MP may be provided as at least one of a permanent magnet and an electromagnet.

Accordingly, a coupling force between the deposition substrate BS and the mask sheet MSS may be increased. The arranged position, shape, and number of the magnetic plate MP are not limited to any one embodiment, as long as the magnetic plate MP is disposed on the mask sheet MSS and allows the masks MS included in the mask sheet MSS to be coupled to the deposition substrate BS with the magnetic force.

The support plate YK may accommodate the magnetic plate MP. The support plate YK may be coupled to the transfer part DD and may make the magnetic plate MP be in close contact with or be separated from the deposition substrate BS.

The cooling plate may be disposed between the deposition substrate BS and the support plate YK. The cooling plate may provide a function for cooling the deposition substrate BS or the masks MS so that the deposition substrate BS or the masks MS are prevented from being overheated during a deposition process. Accordingly, a deformation of the deposition substrate BS may be prevented. A cooling line or the like into which cooling water or cooled air is injected may be provided inside the cooling plate.

The transfer part DD may be connected to the pressing part PM. The transfer part DD may include the transfer rod ML and a transfer body MC. The transfer body MC may transfer the pressing part PM in a third direction DR3, for example in an upward or downward direction, by the transfer rod ML.

For example, the transfer body MC may be disposed outside the chamber CH. The transfer body MC may be implemented either as a cylinder or a motor. For example, in case that the transfer body MC is a cylinder, the transfer rod ML may be a piston. In case that the transfer body MC is a motor, the transfer rod ML may be implemented as a ball screw shaft that may move upward or downward according to the rotation of the motor. However, an embodiment is not limited to any one embodiment as long as the transfer part DD is a device capable of moving the pressing part PM.

The mask sheet MSS may be disposed inside the chamber CH, and the deposition substrate BS may be disposed on the mask sheet MSS. The mask sheet MSS may include a frame FR, the masks MS, and support sticks SS. The frame FR, the masks MS, and the support sticks SS may include at least one of an invar and stainless steel.

The frame FR may be placed on the holder part SP to support the masks MS and the support sticks SS. A frame opening F-OP may be defined in the frame FR. The shape, position, and number of the frame FR are not limited to any one embodiment.

FIG. 2 illustrates a schematic plan view of a mask sheet MSS. The mask sheet MSS according to the embodiment may include a frame FR, first to fourth masks MS1, MS2, MS3, and MS4, and first to third support sticks SS1, SS2, and SS3. In an embodiment, the first to fourth masks MS1, MS2, MS3, and MS4 may be fine metal masks (FMM).

The first to fourth masks MS1, MS2, MS3, and MS4 may be arranged along a first direction DR1 and may extend along a second direction DR2. FIG. 2 illustrates that four masks (for example, first to fourth masks MS1, MS2, MS3, and MS4) are disposed in the frame FR, but the number and shape of the masks are not limited to any one embodiment.

The first to fourth masks MS1, MS2, MS3, and MS4 may each include a deposition part DA and a body part NDA adjacent to the deposition part DA.

Deposition openings M-OP passing through the deposition part DA may be defined in the deposition part DA. The deposition openings M-OP may overlap a frame opening F-OP. A deposition material sprayed from the deposition source ES illustrated in FIG. 1 may pass through the frame opening F-OP and the deposition openings M-OP to be deposited onto the deposition substrate BS.

According to the embodiment, the first to fourth masks MS1, MS2, MS3, and MS4 which are used to manufacture a large-area display panel may each have a width WD in a range of about 400 mm to about 1000 mm in the first direction DR1. The first to fourth masks MS1, MS2, MS3, and MS4 may each include an invar.

The first to fourth masks MS1, MS2, MS3, and MS4 may be coupled to the frame FR through a welding process. Thus, first welding projections WBO formed through the welding process may be formed in one portion of the body part NDA of each of the first to fourth masks MS1, MS2, MS3, and MS4.

The first to third support sticks SS1, SS2, and SS3 may be disposed under the first to fourth masks MS1, MS2, MS3, and MS4. The first to third support sticks SS1, SS2, and SS3 may be disposed between body parts NDA, which are disposed adjacent to each other along the first direction DR1, among the body parts NDA included in the first to fourth masks MS1, MS2, MS3, and MS4.

For example, the first support stick SS1 may be disposed between the body part NDA of the first mask MS1 and the body part NDA of the second mask MS2. The second support stick SS2 may be disposed between the body part NDA of the second mask MS2 and the body part NDA of the third mask MS3. The third support stick SS3 may be disposed between the body part NDA of the third mask MS3 and the body part NDA of the fourth mask MS4.

The body parts NDA adjacent to each other may be coupled to the first to third support sticks SS1, SS2, and SS3 through a welding process. Thus, second welding projections WMO formed through the welding process may be formed on the body parts NDA overlapping the first to third support sticks SS1, SS2, and SS3.

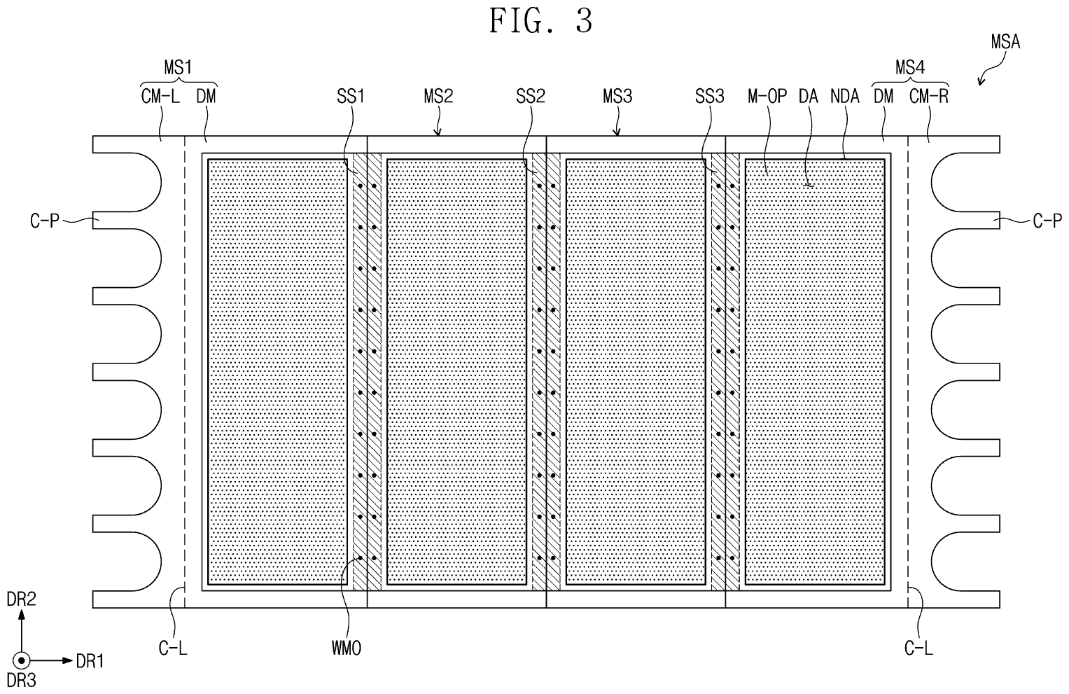

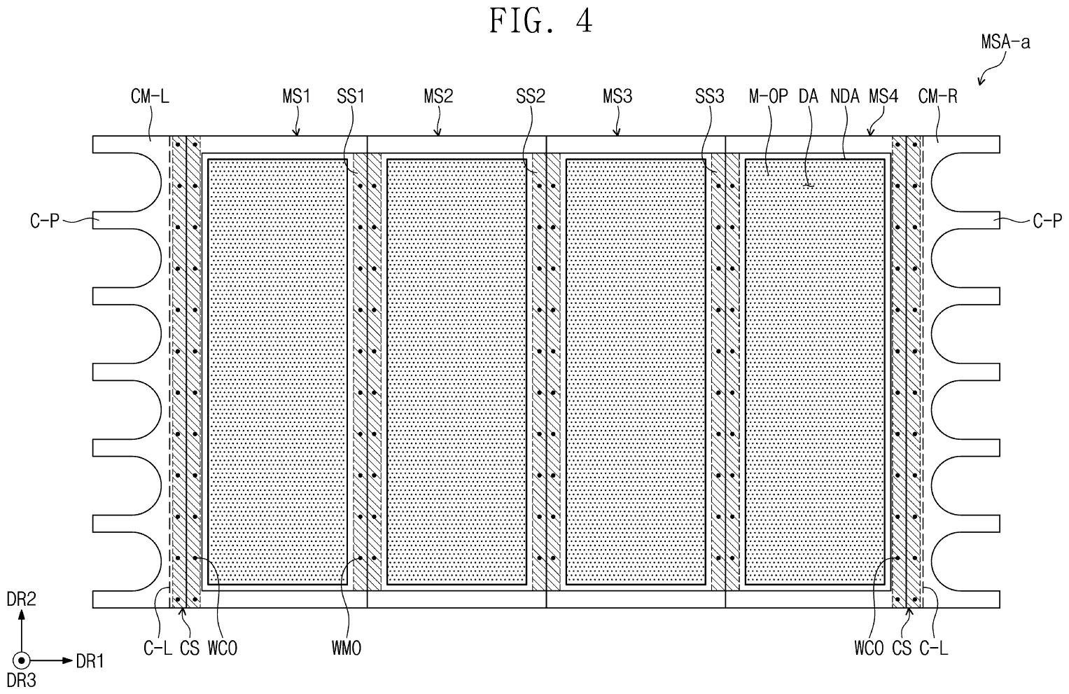

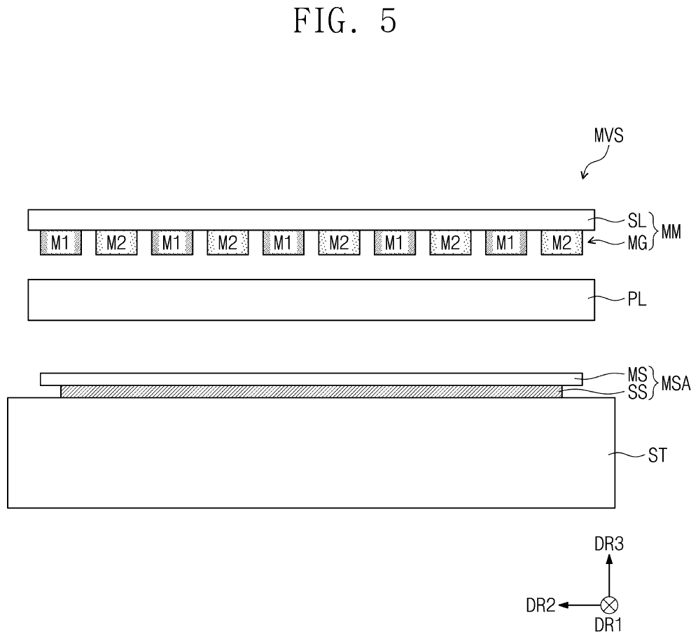

FIG. 3 is a schematic plan view of a mask assembly according to an embodiment. FIG. 4 is a schematic plan view of an initial mask assembly according to an embodiment. Mask assemblies MSA and MSA-a to be described with reference to FIGS. 3 and 4 may be substrates transferred, conveyed, or stored by a mask assembly transfer device MVS according to the embodiment which will be described with reference to FIG. 5. The mask assembly MSA or MSA-a may be defined as being in a state in which only the masks (for example, first to fourth masks MS1, MS2, MS3, and MS4) and the support sticks (for example, first to third support sticks SS1, SS2, and SS3) are coupled in the mask sheet MSS illustrated in FIG. 2 before being coupled to the frame FR illustrated in FIG. 2. Thus, the mask assembly MSA or MSA-a may be in a state in which the mask assembly includes the masks and the support sticks only.

Referring to FIG. 3, the mask assembly MSA according to an embodiment may include first to fourth masks MS1, MS2, MS3, and MS4 and first to third support sticks SS1, SS2, and SS3.

The first to fourth masks MS1, MS2, MS3, and MS4 may be arranged along a first direction DR1 and may extend along a second direction DR2. The first to fourth masks MS1, MS2, MS3, and MS4 may each include a deposition part DA and a body part NDA adjacent to the deposition part DA. Deposition openings M-OP passing through the deposition part DA may be defined in the deposition part DA. The first to third support sticks SS1, SS2, and SS3 may be disposed under the first to fourth masks MS1, MS2, MS3, and MS4. The first to third support sticks SS1, SS2, and SS3 may be disposed between body parts NDA, which are disposed adjacent to each other along the first direction DR1, among the body parts NDA included in the first to fourth masks MS1, MS2, MS3, and MS4. The body parts NDA adjacent to each other may be coupled to the first to third support sticks SS1, SS2, and SS3 through a welding process. Thus, second welding projections WMO formed through the welding process may be formed on the body parts NDA overlapping the first to third support sticks SS1, SS2, and SS3.

According to this embodiment, the first mask MS1 and the fourth mask MS4 which are disposed on the outermost side may each include a main part DM having the deposition part DA and the body part NDA and either clamping parts CM-L or CM-R protruding from the main part DM. The clamping parts CM-L and CM-R may each include protrusion patterns C-P protruding from the main part DM along the first direction DR1. A shape recessed toward the main part DM may be formed between the protrusion patterns C-P adjacent to each other along the second direction DR2.

To prevent the first to fourth masks MS1, MS2, MS3, and MS4 from being deformed and being welded to the frame FR during a process for welding the mask assembly MSA to the frame FR illustrated in FIG. 2, the welding process may be performed on the frame FR while the protrusion patterns C-P are grasped and stretched along the first direction DR1 by a separate device such as a clamping device or the like.

According to this embodiment, the main part DM and a first clamping part CM-L of the first mask MS1 may be provided as an integrated pattern. A cutting line C-L may be defined in the first mask MS1. The first clamping part CM-L may be removed from the main part DM along the cutting line C-L while the main part DM of the first mask MS1 is coupled to the frame FR through a welding process. This may also be similarly applied to the main part DM and a second clamping part CM-R included in the fourth mask MS4.

In describing the mask assembly MSA-a in FIG. 4, differences from the mask assembly MSA illustrated in FIG. 3 will be explained. The mask assembly MSA-a according to this embodiment may include a first clamping part CM-L coupled to a first mask MS1 and a second clamping part CM-R coupled to a fourth mask MS4.

According to this embodiment, additional support sticks CS may further be included to couple the first and fourth masks MS1 and MS4 to the first and second clamping parts CM-L and CM-R. The first mask MS1 and the first clamping part CM-L may be coupled to the additional support stick CS through a welding process. Thus, third welding projections WCO may be formed on the first mask MS1 and the first clamping part CM-L. The fourth mask MS4 and the second clamping part CM-R may be coupled to the additional support stick CS though a welding process. Thus, the third welding projections WCO may be formed on the fourth mask MS4 and the second clamping part CM-R.

According to this embodiment, a cutting line C-L may be defined in each of the first and second clamping parts CM-L and CM-R. The first and second clamping parts CM-L and CM-R may be removed along the cutting line C-L while the first and fourth masks MS1 and MS4 are coupled to the frame FR through a welding process.

FIGS. 5 to 9 are schematic cross-sectional views illustrating a mask assembly transfer method according to an embodiment. FIGS. 5 to 9 illustrate a transfer method of the mask assembly MSA illustrated in FIG. 3, but the transfer method may also be applied to the mask assembly MSA-a illustrated in FIG. 4, and the disclosure is not limited to any one embodiment. Duplicated explanations of the mask assembly MSA illustrated in FIG. 3 may be omitted.

Referring to FIG. 5, a mask assembly transfer device MVS may include a stage ST on which a mask assembly MSA is disposed, a plate PL disposed on the stage ST, and a magnetic member MM disposed on the plate PL.

The mask assembly MSA may be disposed on the stage ST. The stage ST may be provided as a cuboid shape. According to an embodiment, the stage ST may further include suction holes for fastening the mask assembly MSA by forming an air current.

The plate PL may be disposed on the stage ST. The plate PL may include a driving motor which is separated from the magnetic member MM and performs upward and downward movements along a third direction DR3 or performs a horizontal movement along a first direction DR1 and a second direction DR2.

The plate PL may be disposed between the mask assembly MSA and the magnetic member MM, and the mask assembly MSA may be prevented from being deformed in case that a magnetic force is applied to the magnetic member MM. Thus, the plate PL may include a non-magnetic material. For example, the plate PL may include at least one of glass and acrylic.

The magnetic member MM may be disposed on the plate PL. In case that a magnetic force is formed in the magnetic member MM, the mask assembly MSA and the magnetic member MM may not be in direct contact but indirectly coupled to each other with the plate PL therebetween and transferred integrally.

The magnetic member MM may include a magnetic body MG and a support part SL. The magnetic body MG may include first magnetic bodies M1 and second magnetic bodies M2 each extending along the first direction DR1 and arranged along the second direction DR2. The first magnetic bodies M1 and the second magnetic bodies M2 may be separated from the support part SL and replaced individually.

The first magnetic bodies M1 and the second magnetic bodies M2 may be alternately arranged along the second direction DR2. In an embodiment, the first magnetic bodies M1 and the second magnetic bodies M2 may have polarities different from each other.

According to the embodiment, an extending direction of the first magnetic bodies M1 and the second magnetic bodies M2 may cross an extending direction of a support stick SS. For example, the first magnetic bodies Ml and the second magnetic bodies M2 may extend along the first direction DR1, and the support stick SS may extend along the second direction DR2. Thus, as a force applied to the support stick SS along the second direction DR2 from the first magnetic bodies M1 and the second magnetic bodies M2, a repulsive force and an attractive force may be alternately applied.

Hereinafter, with reference to FIGS. 5 to 9, a mask assembly transfer method using the aforesaid mask assembly transfer device MVS will be described.

Referring to FIG. 5, the mask assembly transfer method may include a step of disposing a mask assembly MSA on a stage ST.

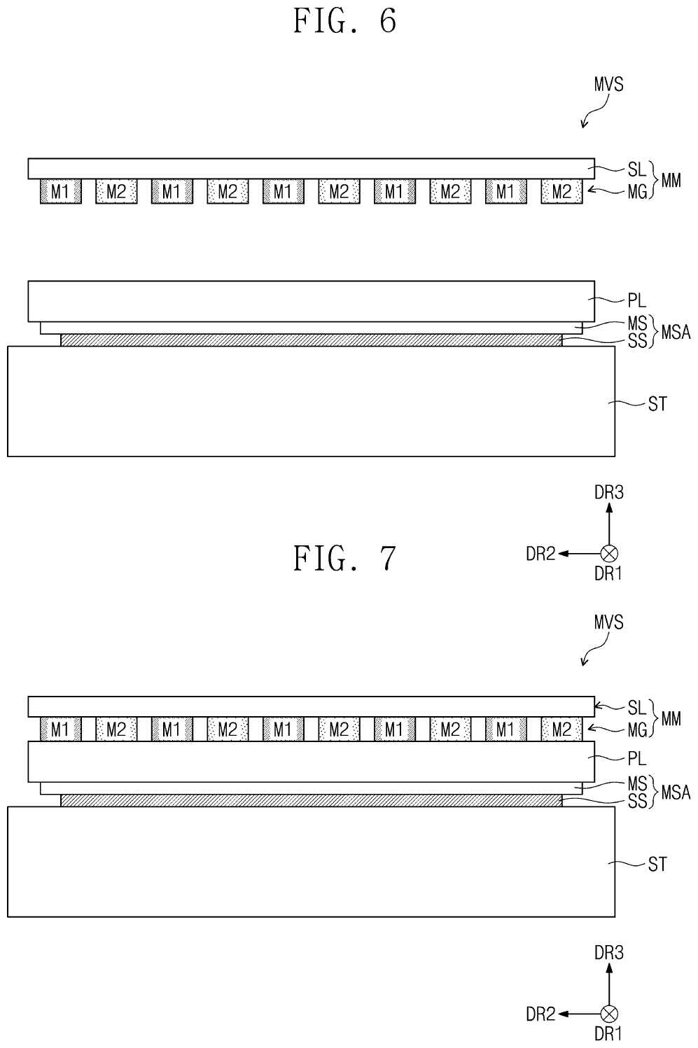

Thereafter, referring to FIG. 6, the mask assembly transfer method may include a step of moving a plate PL downward. The plate PL may be moved along a third direction DR3 by a separate transfer device provided with a motor. The plate PL may be moved downward to make contact with (or to be attached to) the mask assembly MSA.

Thereafter, referring to FIG. 7, the mask assembly transfer method may include a step of moving a magnetic member MM downward. The magnetic member MM may be moved along the third direction DR3 by a separate transfer device provided with a motor. The magnetic member MM may be moved downward to make contact with (or to be attached to) the plate PL.

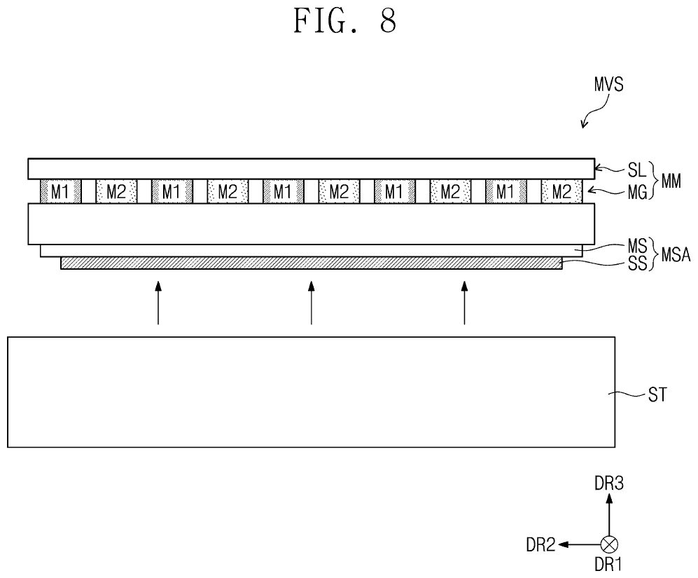

Thereafter, referring to FIG. 8, the mask assembly transfer method may include a step of attaching the mask assembly MSA to the magnetic member MM and a step of raising the magnetic member MM.

First magnetic bodies M1 and second magnetic bodies M2 included in the magnetic member MM may be arranged along a second direction DR2. The first magnetic bodies M1 and the second magnetic bodies M2 may each extend along a first direction DR1. The first magnetic bodies M1 and the second magnetic bodies M2 may be alternately arranged along the second direction DR2. A support stick SS for coupling the masks MS may extend along the second direction DR2.

In case that a magnetic force is applied to the magnetic member MM, different magnetic forces may be applied to the first magnetic bodies M1 and the second magnetic bodies M2. For example, the first magnetic bodies M1 may have an N-pole, and the second magnetic bodies M2 may have an S-pole, or vice versa. Since the masks MS and the support stick SS may include an invar, the mask assembly MSA may be attached to the magnetic member MM with the plate PL therebetween in case that a magnetic force is applied to the magnetic member MM. The magnetic member MM may move upward along the third direction DR3 while the plate PL and the mask assembly MSA are coupled to the magnetic member MM.

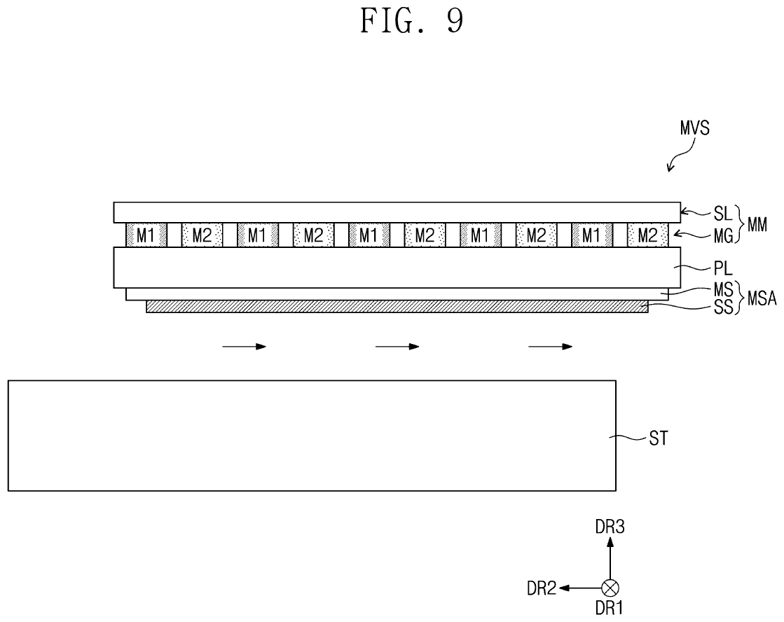

Thereafter, referring to FIG. 9, the mask assembly transfer method may include a step of transferring the magnetic member MM to the outside of the stage ST. The mask assembly MSA, which is attached to the magnetic member MM, may be transferred, stored, or conveyed in a state in which the mask assembly MSA is not coupled to the frame FR illustrated in FIG. 2. The mask assembly MSA may be coupled to the frame FR illustrated in FIG. 2, and the deposition process may be performed on the deposition substrate BS using the deposition apparatus EA, illustrated in FIG. 1.

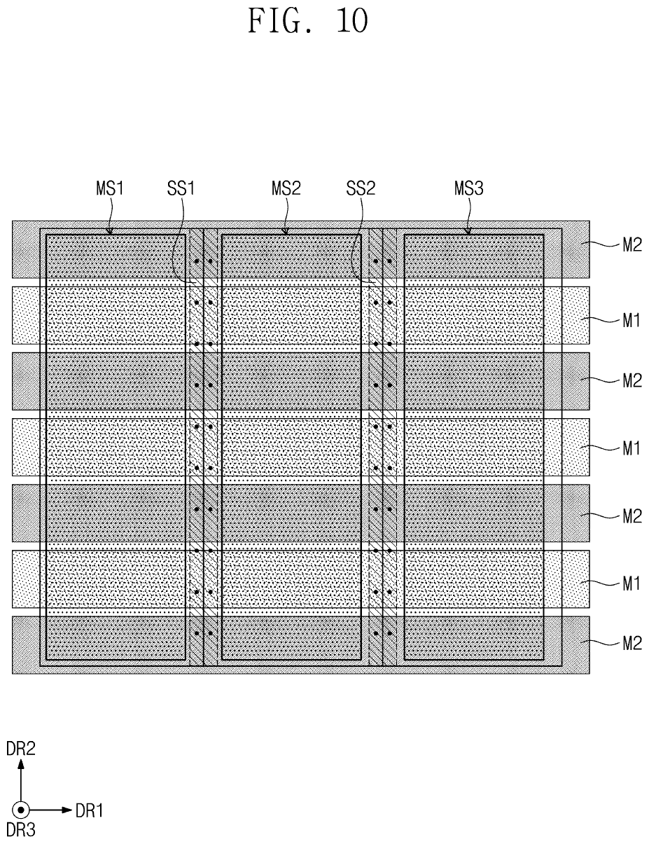

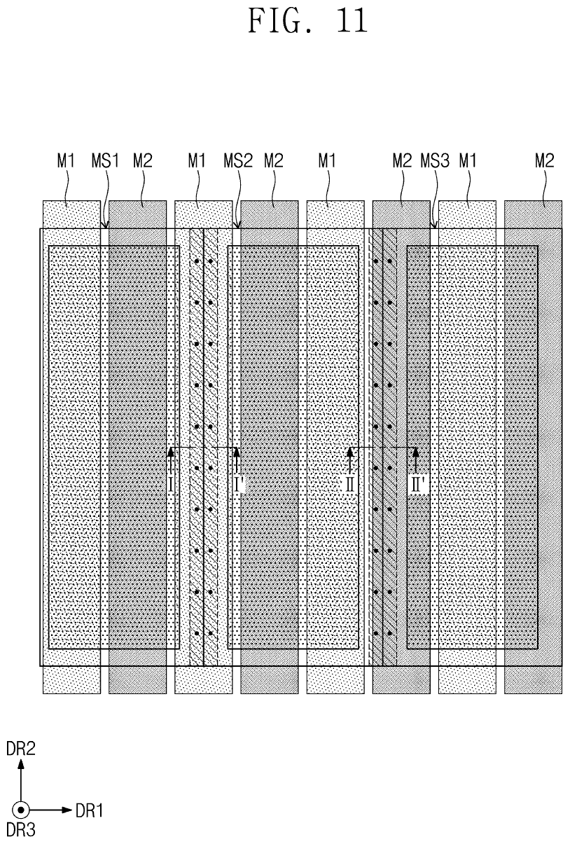

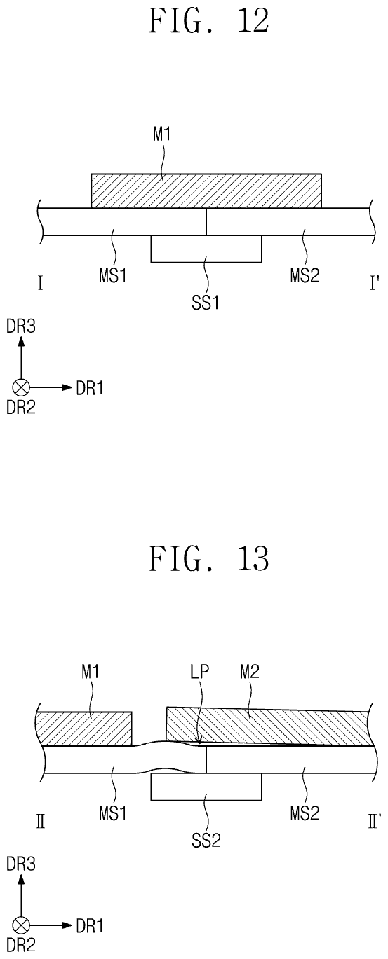

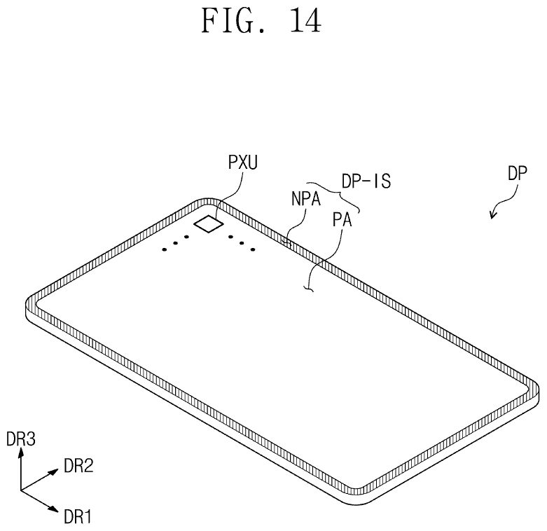

FIG. 10 is a schematic plan view of a mask assembly and a magnetic body according to an embodiment. FIG. 11 is a schematic plan view of a mask assembly and magnetic bodies according to Comparative Examples. FIG. 12 is a schematic cross-sectional view taken along line I-I′ in FIG. 11. FIG. 13 is a schematic cross-sectional view taken along line II-II′ in FIG. 11.

As illustrated in FIG. 10, first and second magnetic bodies M1 and M2 according to the embodiment may be arranged in a direction crossing first and second support sticks SS1 and SS2. Accordingly, a magnetic force applied to the first and second support sticks SS1 and SS2 along a second direction DR2 may be uniform.

On the other hand, referring to FIGS. 11 to 13, first and second magnetic bodies M1 and M2 according to Comparative Examples may extend along a second direction DR2, in the same direction as first and second support sticks SS1 and SS2 and may be arranged along a first direction DR1.

As illustrated in FIG. 12, a first support stick SS1 may be disposed in a center of a first magnetic body M1 and may receive a uniform magnetic force from the first magnetic body M1. However, as illustrated in FIG. 13, a second magnetic body M2 may be biased toward the first direction DR1 from a center of a second support stick SS2, and thus a repulsive force may be generated on the second support stick SS2. A lifting phenomenon LP, in which a first mask MS1 is lifted from the second support stick SS2, may occur due to the repulsive force, thereby resulting in a deposition defect in case that a deposition process is performed through the deposition apparatus EA in FIG. 1.

According to the embodiment illustrated in FIG. 10, since the first and second support sticks SS1 and SS2 and the magnetic bodies M1 and M2 are arranged crossing each other, a magnetic force applied to the first and second support sticks SS1 and SS2 from the magnetic bodies M1 and M2 may be uniform. Accordingly, it is possible to provide a mask assembly transfer device MVS with which a shape of a mask assembly MSA is not deformed, and a transfer method of the mask assembly MSA using the same.

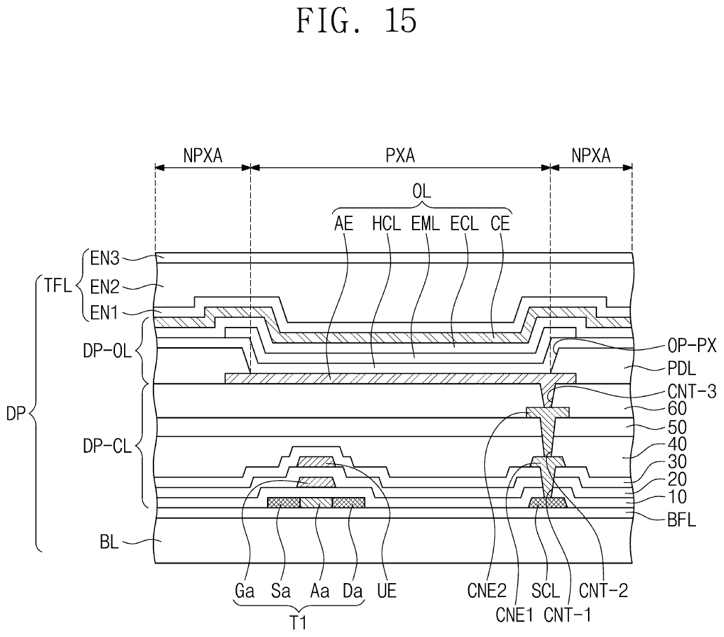

FIG. 14 is a schematic perspective view of a display panel according to an embodiment. FIG. 15 is a schematic cross-sectional view of a display panel according to an embodiment. FIGS. 14 and 15 illustrate an example of a display panel DP which is formed through the deposition apparatus EA and the mask sheet MSS, illustrated in FIG. 1.

Referring to FIGS. 14 and 15, the display panel DP may display an image through a display surface DP-IS. A top surface of a member disposed on the uppermost side of the display panel DP may be defined as the display surface DP-IS.

The display surface DP-IS may be parallel to a plane defined by a first direction DR1 and a second direction DR2. A normal direction of the display surface DP-IS, for example a thickness direction of the display panel DP, may indicate a third direction DR3. A front surface (or top surface) and a rear surface (or bottom surface) of each of layers or units to be described below may be distinguished based on the third direction DR3.

The display panel DP may include a display region PA and a non-display region NPA. A light-emitting layer included in a pixel may be disposed in the display region PA, and the light-emitting layer of the pixel may not be disposed in the non-display region NPA. The non-display region NPA may be defined along an edge of the display surface DP-IS. The non-display region NPA may surround the display region PA. In an embodiment, the non-display region NPA may be omitted or may be disposed on one side of the display region PA.

Referring to FIG. 15, in an embodiment, the display panel DP may be a light-emitting display panel. FIG. 15 illustrates a cross-section corresponding to one of pixels, and a cross-section corresponding to a transistor T1, and a light-emitting element OL.

The display panel DP may include a base layer BL, a circuit element layer DP-CL disposed on the base layer BL, a display element layer DP-OL disposed on the circuit element layer DP-CL, and an encapsulation layer TFL disposed on the display element layer DP-OL.

The base layer BL may include a synthetic resin layer. The base layer BL may be formed by forming a synthetic resin layer on a support substrate, which is used in manufacture of the display panel DP, forming a conductive layer and an insulation layer on the synthetic resin layer, and removing the support substrate.

The circuit element layer DP-CL may include at least one insulation layer and a circuit element. The circuit element may include a signal line, a driving circuit of a pixel, or the like. The circuit element layer DP-CL may be formed through a process for forming an insulation layer, a semiconductor layer, and a conductive layer through coating, deposition, or the like and a process for patterning the insulation layer, the semiconductor layer, and the conductive layer through photolithography.

In this embodiment, the circuit element layer DP-CL may include a buffer layer BFL and first to sixth insulation layers 10, 20, 30, 40, 50, and 60. The first to sixth insulation layers 10, 20, 30, 40, 50, and 60 may include at least one of an inorganic film and an organic film. The buffer layer BFL may include an inorganic film. At least one of the fifth and sixth insulation layers 50 and 60 may include an organic film.

FIG. 15 illustrates an arrangement relationship of an active Aa, a gate Ga, a source Sa, and a drain Da which constitute the transistor T1.

The active Aa may include a polysilicon semiconductor. However, an embodiment is not limited thereto, and the active Aa may include a metal oxide semiconductor. The source Sa and the drain Da may be regions having greater doping concentration than the active Aa, and thus may serve as an electrode.

The circuit element layer DP-CL may include first and second connection electrodes CNE1 and CNE2 which connect a signal line SCL and an anode AE. The first connection electrode CNE1 may be connected to the signal line SCL via a first contact hole CNT-1, and the second connection electrode CNE2 may be connected to the first connection electrode CNE1 via a second contact hole CNT-2. The anode AE may be connected to the second connection electrode CNE2 via a third contact hole CNT-3.

The display element layer DP-OL may include a pixel-defining film PDL and the light-emitting element OL. The light-emitting element OL may be an organic light-emitting diode or a quantum-dot light-emitting diode. The anode AE may be disposed on the sixth insulation layer 60. A pixel opening OP-PX of the pixel-defining film PDL may expose at least one portion of the anode AE. The pixel opening OP-PX of the pixel-defining film PDL may define a light-emitting region PXA. A non-light emitting region NPXA may surround the light-emitting region PXA.

A hole control layer HCL and an electron control layer ECL may be disposed in the light-emitting region PXA and the non-light emitting region NPXA in common. A light-emitting layer EML may include a light-emitting substance and may be provided in a pattern form to correspond to the pixel opening OP-PX. The light-emitting layer EML may be deposited through a method different from those for the hole control layer HCL and the electron control layer ECL, which have a film shape. The hole control layer HCL and the electron control layer ECL may be formed in pixels in common using an open mask.

The light-emitting layer EML may be formed through the mask sheet MSS illustrated in FIG. 1. The deposition substrate BS illustrated in FIG. 1 may be defined as being in a state in which layers from the base layer BL to the pixel-defining film PDL, the anode AE, and the hole control layer HCL, illustrated in FIG. 15, are formed.

A cathode CE may be disposed on the electron control layer ECL. The encapsulation layer TFL may be disposed on the cathode CE. The encapsulation layer TFL may be a thin-film encapsulation layer for encapsulating the display element layer DP-OL. The encapsulation layer TFL may include multiple thin films. The thin films may include inorganic films EN1 and EN3 and an organic film EN2. The encapsulation layer TFL may include an insulation layer for encapsulating the display element layer DP-OL and multiple insulation layers for improving emission efficiency.

According to an embodiment, in case that transferring a large-area mask assembly, magnetic bodies are arranged in a perpendicular direction to support sticks, and thus a repulsive force is not applied to the mask assembly, thereby stably transferring the mask assembly.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

Although embodiments have been disclosed for illustrative purposes, those skilled in the art will appreciate that various modifications, additions and substitutions are possible, without departing from the scope and spirit of the disclosure as disclosed in the accompanying claims and their equivalents.

The referred drawings and the detailed description of the disclosure described are merely examples of the disclosure, are used for merely describing the disclosure, and are not intended to limit the meaning and the scope of the disclosure described in the claims. Therefore, those skilled in the art may understand that various modifications and equivalent other embodiments are possible from the teachings of the disclosure.

What is claimed is:

1. A mask assembly transfer device comprising:
a stage supporting a mask assembly;
a magnetic member disposed on the stage; and
a plate disposed between the stage and the magnetic member, wherein the mask assembly includes:
masks arranged in a first direction and disposed on the stage, and
support sticks disposed between the masks and arranged in the first direction, each extending in a second direction crossing the first direction,
the magnetic member includes:
a support part; and
first magnetic bodies and second magnetic bodies which are coupled to the support part and arranged in the second direction, each extending in the first direction,
the first magnetic bodies and the second magnetic bodies have polarities different from each other, and
the first magnetic bodies and the second magnetic bodies are alternately arranged in the second direction.

2. The mask assembly transfer device of claim 1, wherein the plate comprises at least one of glass and acrylic.

3. The mask assembly transfer device of claim 1, wherein the plate moves downward to make contact with the mask assembly.

4. The mask assembly transfer device of claim 3, wherein the magnetic member moves downward to make contact with the plate.

5. The mask assembly transfer device of claim 4, wherein, in case that a magnetic force is applied to the first magnetic bodies and the second magnetic bodies, the mask assembly is attached to the plate.

6. The mask assembly transfer device of claim 5, wherein
the mask assembly is attached, by the magnetic force, to the magnetic member, with the plate disposed between the mask assembly and the magnetic member, and
the magnetic member transfers the mask assembly from the stage.

7. The mask assembly transfer device of claim 5, wherein the first magnetic bodies and the second magnetic bodies are each separable from the support part and replaceable.

8. The mask assembly transfer device of claim 1, wherein
each of the masks comprises a deposition part in which deposition openings are formed, and a body part surrounding the deposition part, and
among body parts of each of the masks, the body parts adjacent to each other in the first direction are coupled to the support sticks.

9. The mask assembly transfer device of claim 8, wherein the body parts are coupled to the support sticks through a welding process.

10. The mask assembly transfer device of claim 1, wherein, in plan view, the first magnetic bodies and the second magnetic bodies each cross the support sticks.

11. The mask assembly transfer device of claim 1, wherein each of the masks has a width in a range of about 400 mm to about 1000 mm in the first direction.

12. The mask assembly transfer device of claim 8, wherein, among the masks, each of the masks disposed on an outermost side in the first direction further comprises a clamping part connected to the body part.

13. The mask assembly transfer device of claim 12, further comprising additional support sticks overlapping the clamping part and the body part,
wherein the clamping part and the body part are coupled to the additional support stick through a welding process.

14. The mask assembly transfer device of claim 1, wherein the support sticks are disposed between the masks and the stage.

15. The mask assembly transfer device of claim 1, wherein the masks and the support sticks comprise an invar.

16. A mask assembly transfer method comprising:
disposing a mask assembly on a stage;
moving a plate downward so that the plate makes contact with the mask assembly;
moving a magnetic member downward so that the magnetic member makes contact with the plate;
attaching the mask assembly to the magnetic member, with the plate disposed between the mask assembly and the magnetic member, by applying a magnetic force to the magnetic member; and
transferring the magnetic member to outside of the stage while the mask assembly is attached to the magnetic member, wherein
the mask assembly includes:
masks arranged in a first direction and disposed on the stage, and
support sticks disposed between the masks and arranged in the first direction, each extending in a second direction crossing the first direction,
the magnetic member includes first and second magnetic bodies arranged in the second direction, each extending in the first direction, and
the first magnetic bodies and the second magnetic bodies have polarities different from each other and are alternately arranged in the second direction.

17. The mask assembly transfer method of claim 16, wherein the plate comprises at least one of glass and acrylic.

18. The mask assembly transfer method of claim 16, wherein, in plan view, the first magnetic bodies and the second magnetic bodies each cross the support sticks.

19. The mask assembly transfer method of claim 16, wherein the support sticks are disposed between the masks and the stage.

20. The mask assembly transfer method of claim 16, wherein each of the masks has a width in a range of about 400 mm to about 1000 mm in the first direction.
